(19) United States
(12) Patent Application Publication
(10) Pub. No.: US 2019/0157538 A1
(43) Pub. Date: May 23, 2019

(54) MECHANICALLY INDUCED SOLID SOLUTION TRANSFORMATION IN TE-SN BINARY SYSTEM BY BALL MILLING PROCESS

(71) Applicant: King Fahd University of Petroleum and Minerals, Dhahran (SA)

(72) Inventors: Abbas Saeed Hakeem, Dhahran (SA); Tahar Laoui, Dhahran (SA); Zain Hassan Abdallah Yamani, Dhahran (SA); Saleh Mohammed Mabkhoot AlMansour, Dhahran (SA); Muhammad Qamaruddin, Dhahran (SA)

(73) Assignee: King Fahd University of Petroleum and Minerals, Dhahran (SA)

(21) Appl. No.: 15/815,791

(22) Filed: Nov. 17, 2017

(51) Int. Cl. H01L 35/34

(52) U.S. Cl. CPC H01L 35/34; H01L 35/16

(57) ABSTRACT

A method for ball milling a SnTe alloy into a solid solution or a face-centered cubic crystalline (fcc) phase. A SnTe alloy in the form of nanoparticles of a solid solution or a face-centered cubic crystalline (fcc) phase that can be prepared by this method.

### BACKGROUND OF THE INVENTION

### Field of the Invention

A method for ball milling a SnTe material or alloy into a solid solution or a face-centered cubic crystalline (fcc) phase. A SnTe material or alloy in the form of nanoparticles (nanocrystals) of a solid solution or a face-centered cubic crystalline (fcc) phase that can be prepared by this method.

### Description of the Related Art

Thermoelectric materials such as tin telluride alloys are used to directly convert energy into electric current and vice versa, and for many other applications related to energy efficiency; Xu, B., et al., Highly Porous Thermoelectric Nanocomposites with Low Thermal Conductivity and High Figure of Merit from Large-Scale Solution-Synthesized Bi2Te2.5Se0.5 Hollow Nanostructures. Angewandte Chemie International Edition, 2017, 56(13): p. 3546-3551; Snyder, G. J. and E. S. Toberer, Complex thermoelectric materials. Nat Mater, 2008. 7(2): p. 105-114; Shi, X. and L. Chen, Thermoelectric materials step up. Nat Mater, 2016. 15(7): p. 691-692; Tan, G., et al., SnTe—Agbite2 as an efficient thermoelectric material with low thermal conductivity. Journal of Materials Chemistry A, 2014. 2(48): p. 20849-20854; and Gao, M.-R., et al., Nanostructured metal chalcogenides: synthesis, modification, and applications in energy conversion and storage devices. Chemical Society Reviews, 2013. 42(7): p. 2986-3017.

Tin telluride is a IV-VI narrow band gap semiconductor and has direct band gap of 0.18 eV; Chen, Y., et al., SnTe—AgSbTe₂ Thermoelectric Alloys. Advanced Energy Materials, 2012. 2(1): p. 58-62. A phase diagram of a SnTe system reveals a stoichiometric range characteristic of many binary compounds; Jun-ichi, U., J. Manu, and O. Toshihiro, Tin-Tellurium Phase Diagram in the Vicinity of Stannous Telluride SnTe. Japanese Journal of Applied Physics, 1962. 1(5): p. 277. Tin telluride normally forms p-type semiconductor (extrinsic semiconductor) due to tin vacancies and is a low temperature superconductor which has potential thermoelectric applications; Junichi, id.; Hein, R. A. and P. H. E. Meijer, Critical Magnetic Fields of Superconducting SnTe. Physical Review, 1969. 179(2): p. 497-511; Tan, G., et al., Codoping in SnTe: Enhancement of Thermoelectric Performance though Synergy of Resonance Levels and Band Convergence. Journal of the American Chemical Society, 2015. 137(15): p. 5100-5112; Tan, G., et al., High Thermoelectric Performance of p-Type SnTe via a Synergistic Band Engineering and Nanostructuring Approach. Journal of the American Chemical Society, 2014. 136(19): p. 7006-7017; Bierly, J. N., L. Muldawer, and O. Beckman, The continuous rhombohedral-gubic transformation in GeSnTeTe allots. Acta Metallurgica, 1963. 11(5): p. 447-454.

Tin telluride contains tin (Sn) and tellurium (Te) and can be admixed or alloyed with other elements, such as lead, depending on its application. Conventionally SnTe materials were prepared by melting raw materials to form a SnTe alloy and pouring and casting the resulting molten liquid into ingots.

Tin telluride materials may be produced by mechanical alloying (MA) according to conventional powder metallurgy techniques. These include mixing metallic powders in solid forms and ball milling them to repetitively form welds, fractures and re-welds in the metallic powders. Ball milling has been used to produce both equilibrium and non-equilibrium forms of mixed metallic powders in their elemental or pre-alloyed form; Manna, I., et al., Development of amorphous and nanocrystalline Al₆₅Cu₃₅₋ₓZrₓ alloys by mechanical alloying. Materials Science and Engineering: A, 2004. 379(1-2): p. 360-365. Non-equilibrium forms of powder mixtures have been synthesized to produce supersaturated solid solutions or metastable crystalline materials. Nevertheless, the synthesis of alloys and intermetallic materials by ball milling and other mechanical alloying procedures has been criticized due to the development of amorphous nanostructures and disordering of ordered materials Sherif El-Eskandarany, M., et al., Cyclic phase transformations of mechanically alloyed Co75Ti25 powders. Acta Materialia, 2002. 50(5): p. 1113-1123; Saheb, N., M. Shahzeb Khan, and A. S. Hakeem, Effect of Processing on Mechanically Alloyed and Spark Plasma Sintered Al—Al2O3 Nanocomposites. Journal of Nanomaterials, 2015. 2015: p. 13; Al-Aqeeli, N., et al., Synthesis, characterisation and mechanical properties of SiC reinforced Al based nanocomposites processed by MA and SP. Powder Metallurgy, 2013. 56(2): p. 149-157; Saheb, N., et al., Synthesis and spark plasma sintering of Al—Mg—Zr alloys. Journal of Central South University, 2013. 20(1): p. 7-14; Scudino, S., et al., Mechanical alloying and milling of Al—Mg alloys. Journal of Alloys and Compounds, 2009. 483(1-2): p. 2-7; Suryanarayana, C., Mechanical alloying and milling. Progress in Materials Science, 2001. 46(1-2): p. 1-184.

Thermoelectric devices play a vital role in the field of energy and renewable energy applications. However, in order to meet that role, more effective materials are required which are appropriate for various temperatures ranges and applications. Interest in the advancement of thermoelectric materials has increased due to advances in materials development techniques and cognizance of numerous applications in the field; Luo, J., et al., Enhanced Average Thermoelectric Figure of Merit of the PbTe—SrTe—MnTe Alloy. ACS Applied Materials & Interfaces, 2017. 9(10): p. 8729-8736; Zhang, X. and L.-D. Zhao, Thermoelectric materials: Energy conversion between heat and electricity. Journal of Materiomics, 2015. 1(2): p. 92-105; Zhao, L.-D., et al., Ultralow thermal conductivity and high thermoelectric figure of merit in SnSe crystals. Nature, 2014. 508(7496): p. 373-377; Guo, Q., A. Assoud, and H. Kleinke, Improved Bulk Materials with Thermoelectric Figure-of-Merit Greater than 1: Tl10−xSnxTe6 and Tl10−xPhxTe6. Advanced Energy Materials, 2014. 4(14): p. n/a-n/a; Zhang, Q., et al., Enhancement of thermoelectric figure-of-merit by resonant states of aluminium doping in lead selenide. Energ. Environ. Sci., 2012. 5: p. 5246-5251; Wang, L., S. Zheng, and H. Chen, Enhanced Electronic Transport Properties of Se-Doped Sn Te1−xSex Nanoparticle by Microwave-Assisted Solvothermal Method. Journal of Electronic Materials, 2017.46(5): p. 2847-2853.

Thermoelectric devices are generally based on heavily doped semiconductor(s) (see Zhang, X. and L.-D. Zhao, Thermoelectric materials: Energy conversion between heat and electricity. Journal of Materiomics, 2015. 1(2): p. 92-105.) when supplied by a temperature differential, thermoelectric semiconductors respond by virtue of the Seebeck effect to produce a voltage that can be used to drive an external load; Chen, Y., et al., SnTe—AgSbTe₂ Thermoelectric Alloys. Advanced Energy Materials, 2012. 2(1): p. 58-62; Tan, G., et al., High Thermoelectric Performance of p-Type SnTe via a Synergistic Band Engineering and Nanostructuring Approach. Journal of the American Chemical Society, 2014. 136(19): p. 7006-7017; Zhang, Q., et al., Enhancement of thermoelectric figure-of-merit by resonant states of aluminium doping in lead selenide. Energ. Environ. Sci., 2012. 5: p. 5246-5251; Kim, H. and M. Kaviany, Effect of thermal disorder on high figure of merit in PbTe. Phys. Rev. B., 2012. 86: p. 045213; Koenig, J., et al., Titanium forms a resonant level in the conduction hand of PbTe. Physical Rev. B Condensed Matter Mater. Phys., 2011. 84: p. 205126. Several classes of materials are currently under investigation, including complex chalcogenides; Blachnik, R. and R. Igel, Thermodynamic Properties of IV-VI Compounds Lead Chalcogenides. Z Naturforsch B, 1974. 29: p. 625-629; Ravich, Y. I., B. A. Efimova, and V. I. Tamarche, Scattering of current carriers and transport phenomena in Lead Chalcogenides. I. Theory. Phys. Status Solidi B-Basic Res., 1971. 43: p. 11-33; Pei, Y. L. and Y. Liu, Electrical and thermal transport properties of Pb-based chalcogenides: PbTe, PbSe, and PbS. J. Alloy Compd., 2012. 514: p. 40-44; Zhang, Q., et al., High thermoelectric performance by resonant dopant indium in nanostructured SnTe. Proceedings of the National Academy of Sciences, 2013. 110(33): p. 13261-13266; Kafalas, J. A., R. F. Brebrick, and A. J. Strauss, EVIDENCE THAT SnTe IS A SEMICONDUCTOR. Applied Physics Letters, 1964. 4(5): p. 93-94; Santhanam, S. and A. K. Chaudhuri, Transport properties of SnTe interpreted by means of a two valence band model. Materials Research Bulletin, 1981. 16(8): p. 911-917; Brebrick, R. F. and A. J. Strauss, Anomalous Thermoelectric Power as Evidence for Two-Valence Bands in SnTe. Physical Review, 1963. 131(1): p. 104-110; skutterudites (Said, S. M., et al., Enhancement of Thermoelectric Behavior of La_{0.5}Co₄Sb₁₂₋ₓTe x Skutterudite Materials. Metallurgical and Materials Transactions A, 2017: p. 1-9), half-Heusler alloys (Yu, C., et al., High-performance half-Heusler thermoelectric materials Hf₁₋ₓZrₓNiSn_{1-y}Sb_{y} prepared by levitation melting and spark plasma sintering. Acta Materialia, 2009. 57(9): p. 2757-2764), metal oxides (Ichiro Terasaki, et al., Thermoelectric Properties of NaCo₂₋ₓCuₓO₄ Improved by the Substitution of Cu for Co. Japanese Journal of Applied Physics, 2001. 40(1A): p. L65; Gaultois, M. W., et al., Single-step preparation and consolidation of reduced early-transition-metal oxide/metal n-type thermoelectric composites. AIP Advances, 2015. 5(9): p. 097144; Wu, N., et al., Effects of Synthesis and Spark Plasma Sintering Conditions on the Thermoelectric Properties of Ca₃Co₄O_{9+δ}. Journal of Electronic Materials, 2013. 42(7): p. 2134-2142; Kieslich, G., et al., Enhanced thermoelectric properties of the n-type Magneli phase WO2.90: reduced thermal conductivity though microstructure engineering. Journal of Materials Chemistry A, 2014. 2(33): p. 13492-13497); and intermetallic clathates (Saramat, A., et al., Large thermoelectric figure of merit at high temperature in Czochalski-grown clathate Ba₈Ga₁₆Ge₃₀. Journal of Applied Physics, 2006. 99(2): p. 023708; Thermoelectric properties of Ba—Cu—Si clathates. Physical Review B, 2012. 85(16); Crystal growth of intermetallic clathates: Floating zone process and ultra rapid crystallization. Journal of Crystal Growth, 2014; Yan, X., et al., Structural and thermoelectric properties of BaCuSiGe ensuremath clathates. Physical Review B, 2013. 87(11): p. 115206).

In addition, artificial superlattice thin-film structures grown from chemical vapor deposition have been introduced with substantially enhanced ZT (thermoelectric figure of merit) values relative to those of their bulk counterparts. Marking an important development in this area, specially constructed Bi₂Te₃ and Sb₂Te₃ superlattices were shown to exhibit a very high ZT in the range of 2.4 at room temperature; Venkatasubramanian, R., et al., Thin-film thermoelectric devices with high room-temperature figures of merit. Nature, 2001. 413(6856): p. 597-602; Balow, R. B., et al., Synthesis and Characterization of Cu₃(Sb₁₋ₓAsₓ)S₄ Semiconducting Nanocrystal Alloys with Tunable Properties for Optoelectronic Device Applications. Chemistry of Materials, 2017. 29(2): p. 573-578.

A grown thin-film and SnSe, PbTe systems (Tan, G., et al., High Thermoelectric Performance of p-Type SnTe via a Synergistic Band Engineering and Nanostructuring Approach. Journal of the American Chemical Society, 2014. 136(19): p. 7006-7017; Luo, J., et al., Enhanced Average Thermoelectric Figure of Merit of the PbTe—SrTe—MnTe Alloy. ACS Applied Materials & Interfaces, 2017. 9(10): p. 8729-8736; Guo, Q., A. Assoud, and H. Kleinke, Improved Bulk Materials with Thermoelectric Figure-of-Merit Greater than 1: Tl10−xSnxTe6 and Tl10−xPbxTe6. Advanced Energy Materials, 2014. 4(14): p. n/a-n/a; Venkatasubramanian, R., et al., Thin-film thermoelectric devices with high room-temperature figures of merit. Nature, 2001. 413(6856): p. 597-602; Pifer, J. H., Magnetic resonance of Mn²⁺ in PbS PbSe and PbTe. Phys. Rev., 1967. 157: p. 272-276; Vinogradova, M. N., N. V. Kolomoets, and L. M. Sysoeva, Influence of manganese on energy spectrum of p-PbTe. Soviet Phys. Semiconductors, 1971. 5: p. 186-189; Heremans, J. P., et al., Enhancement of thermoelectric efficiency in PbTe by distortion of the electronic density of states. Science, 2008. 321: p. 554-557; Nithiyanantham, U., et al., Low temperature formation of rectangular PbTe nanocrystals and their thermoelectric properties. New Journal of Chemistry, 2016. 40(1): p. 265-277; Harman, T. C., et al., Quantum Dot Superlattice Thermoelectric Materials and Devices. Science, 2002. 297(5590): p. 2229-2232) feature peculiar pyramidal-shaped into Quantum Dot superlattice of PbSe that form spontaneously. The resulting samples possess a ZT of 2 at elevated temperatures (about 200 to 430° C.). Nevertheless, because the vast majority of applications require materials in large quantities, it would therefore be desirable to have compositions that could generate similar ZT values in a bulk material; Zhao, L.-D., et al., Ultralow thermal conductivity and high thermoelectric figure of merit in SnSe crystals. Nature, 2014. 508(7496): p. 373-377; Wang, L., S. Zheng, and H. Chen, Enhanced Electronic Transport Properties of Se-Doped SnTe1−xSex Nanoparticles by Microwave-Assisted Solvothermal Method. Journal of Electronic Materials, 2017. 46(5): p. 2847-2853; Nithiyanantham, U., et al., Low temperature formation of rectangular PbTe nanocrystals and their thermoelectric properties. New Journal of Chemistry, 2016. 40(1): p. 265-277; Harman, T. C., et al., Quantum Dot Superlattice Thermoelectric Materials and Devices. Science, 2002. 297(5590): p. 2229-2232; Pei, Y., et al., Thermopower enhancement in Pb1−xMnxTe alloys and its effect on thermoelectric efficiency. NPG Asia Mater, 2012. 4: p. e28; Wang, F., I. Veremchuk, and S. Lidin, Tuning Crystal Structures and Thermoelectric Properties though Al Doping in ReSil. 75. European Journal of Inorganic Chemistry, 2017. 2017(1): p. 47-55; Han, G., et al., Large-Scale Surfactant-Free Synthesis of p-Type SnTe Nanoparticles for Thermoelectric Applications. Materials, 2017. 10(3): p. 233.

The Seebeck coefficient, also known as the thermoelectric power of a material, is a measure of the magnitude of an induced thermoelectric voltage in response to a temperature difference across that material, as induced by the Seebeck effect, a phenomenon in which a temperature difference between two dissimilar electrical conductors or semiconductors produces a voltage difference between the two substances.

Semiconductors were found to be much more effective thermoelectric generators with Seebeck coefficients in the range of 100 μV/K which exceed a (Seebeck coefficient) values for most metals, typically less than about 10 μV/K. In addition, semiconductors have a higher ratio of electrical conductivity to thermal conductivity when compared to metals. These factors contribute to a greater figure-of-merit for thermoelectric applications. Lead-free SnTe is may be used for thermoelectric solid-state materials and for the harvesting of waste heat recovery.

In view of the limitations of conventional methods, one objective of the present disclosure is to provide new and convenient ways to produce homogenous mixtures of SnTe particles in solid solution and the resultant compositions.

### SUMMARY OF THE INVENTION

A method for forming a SnTe alloy that comprises ball milling Sn powder with Te powder in an atomic ratio ranging from about 1.0:1.1 to 1.1:1.0 for a time and under conditions that produce solid solution, fcc crystalline phase SnTe nanoparticles. A homogenous mixture of SnTe particles produced by this method.

### BRIEF DESCRIPTION OF THE DRAWINGS

FIG. 1A: X-ray diffraction (XRD) pattern.

FIG. 1B: Field emission scanning electron microscope (FESEM) images of Sn.

FIG. 1C. Field emission scanning electron microscope (FESEM) images of Te.

FIG. 1D. Field emission scanning electron microscope (FESEM) images of magnified Te powder before ball milling.

FIG. 2. Graph of particle size distributions after 1, 2, 3, 4, or 5 hours of ball milling which show that an increase in milling time from 1 to 5 hours shifted the curves leftward towards smaller particles sizes.

FIG. 3. X-ray diffraction patterns of SnTe powder mixture milled at ½ h to 5 h.

FIGS. 4A-4D show the field emission scanning electron microscope (FESEM) images; and the low- and high-magnification images of the nanopowders after ball milling for 1 hour.

FIGS. 4E-4H show the field emission scanning electron microscope (FESEM) images; and the low- and high-magnification images of the nanopowders after ball milling for 2 hours.

FIGS. 4I-4L show the field emission scanning electron microscope (FESEM) images; and the low- and high-magnification images of the nanopowders after ball milling for 3 hours.

FIGS. 4M-4P show the field emission scanning electron microscope (FESEM) images; and the low- and high-magnification images of the nanopowders after ball milling for 4 hours.

FIGS. 4Q-4T show the field emission scanning electron microscope (FESEM) images; and the low- and high-magnification images of the nanopowders after ball milling for 5 hours.

FIG. 5A. FESEM micrograph of sample milled for 5 hours.

FIG. 5B: EDX energy dispersive X-ray spectroscopy (EDX) map of Sn.

FIG. 5C: EDX energy dispersive X-ray spectroscopy (EDX) map of Te.

FIG. 5D. EDX energy dispersive X-ray spectroscopy (EDX) map of sample milled for 5 hours.

FIG. 6. TEM image (panel a) and corresponding diffraction pattern (inset panel b).

### DETAILED DESCRIPTION OF THE INVENTION

Ball milling is an inexpensive and convenient way to process or admix large quantities of materials. However, depending on the nature of the materials ball milling can produce different admixtures including amorphous, semi-crystalline, or crystalline forms. Many admixtures, such as binary or ternary mixtures of metals are considered impossible to produce in a particular form, such as in a crystalline or solid solution form by ball milling. To produce these admixtures it is often required to resort to other complicated and expensive methods. The use of ball milling to make a SnTe alloy in solid solution form is described herein, preferably the conditions of ball milling and materials provide a way to produce SnTe in a solid solution (preferably in a fcc crystalline phase) form.

Prominent embodiments of the invention are directed to a method for mechanically inducing a phase transition in tin-telluride (SnTe) to produce SnTe particles where SnTe is in a solid solution. A powder mixture is homogenized with nano-sized powder growth and subsequently the SnTe is transformed from the mechanical mixture of Te and Sn powders into a solid solution of SnTe.

In one embodiment, the method involves top-down ball milling in argon or other inert gas environment with milling time of 5 hours at low milling speed ranging from 50 to 500 RPM, preferably from 200-400 RPM, and more preferably about 300 RPM. Intermediate phases with a similar crystal structure to that of elemental Sn and Te were observed in the ball milled mixtures at various periods of milling time which resolved into a stable phase that is transformed into solid solution of SnTe. An amount of SnTe in a crystalline form (e.g., fcc crystalline phase) during ball milling may range from 0, 10, 20, 30, 40, 50, 60, 70, 80, 90, 95, 99, <100 or 100 wt % and the amount of Te or Sn not in crystalline form (e.g., in amorphous or unalloyed form) may range from 100, 90, 80, 70, 60, 50, 40, 30, 20, 10, 5, 1, 0.5, 0.1 wt. % based on the total weight of Sn and Te.

The morphological and structural modifications at different stages of the ball milling were investigated with X-ray diffraction, field emission scanning electron microscope (FESEM), differential scanning calorimetry (DSC), dynamic light scattering (DLS), density measurements and surface analyzer (BET). A dense pellet was prepared from a freshly prepared solid solution of SnTe by ball milling and sintered using the spark plasma sintering (SPS) technique.

Embodiments include but are not limited to the following.

### Embodiment 1

A method for forming a SnTe alloy comprising:

ball milling Sn powder with Te powder in an atomic ratio ranging from about 1.0:2.0 to 2.0:1.0 for a time and under conditions that produce solid solution, fcc crystalline phase SnTe nanoparticles.

In other embodiments, the atomic ratio of Sn to Te may range from 1.0:2.0 to 2.0:1.0, from 1.0:1.5 to 1.5 to 1.0, or from 1.0:1.1 to 1.1:1.0 or any intermediate sub-ratio thereof that produces a useful or detectable amount of SnTe in solid solution form. In most embodiments of the invention the Sn powder is in the form of the beta allotrope and the Te powder is in crystalline, not amorphous form. In some embodiments, the Sn or Te powders may be in other crystalline or amorphous forms, for example, the Sn powder may be in the form of an alpha allotrope or a beta allotrope or a mixture of both, and the Te powder may be in a crystalline form, an amorphous form, or a mixture of both. In still other embodiments, mixtures of one or more allotropes of Sn or Te may be ball milled.

### Embodiment 2

The method of embodiment 1, wherein the Sn and Te powder is ball milled in a ratio from about 1.0:1.1 to 1.1 to 1.0, and wherein the ball milled Sn powder and Te powder comprise nanoparticles having average diameters of about 50 nm, for example, 30, 35, 40, 45, 50, 55, 60, 65 or 70 nm or any intermediate value within this range.

### Embodiment 3

The method of embodiment 1, wherein the ball milled Sn powder and Te powder comprise nanoparticles having average diameters of >50 nm, such as 55, 60, 65, 70, 75, 80, 85, 90, 100, 125, 150, 175, 200 or >200 nm.

### Embodiment 4

The method of embodiment 1, wherein the ball milling is conducted in an inert atmosphere such as a noble gas (e.g., helium, neon, argon, krypton, xenon) or other gas that does not substantially interact with Sn or Te under ball milling conditions.

### Embodiment 5

The method of embodiment 1, wherein ball milling is performed for about 3.0 to 7 hours at about 200 to 400 RPM or any intermediate value within these two ranges, such as 3, 3.5, 4, 4.5, 5, 5.5, 6, 6.5, <7 or 7 hours; or 200, 250, 300, 350 or 400 rpm. Other time periods or RPM values outside of these ranges may also be used provided that they produce SnTe in solid solution form.

### Embodiment 6

The method of embodiment 1, wherein ball milling is performed for about 4.0 to 6.0 hours at about 250 to 350 RPM or any intermediate value within these two ranges. In some embodiments, ball milling may be performed for 0.5, 1, 1.5, 2, 2.5, 3, 3.5, 4, 4.5, 5, 5.5, 6, 6.5, 7.5, 8, 8.5, 9, 9.5 or 10 hours.

### Embodiment 7

The method of embodiment 1, wherein the balls used for ball milling have diameters of about 4-8 mm or any intermediate value within this range. In other embodiments, the diameter of the ball or balls may range from 1, 2, 3, 4, 5, 6, 7, 8, 9, 10, 11, or 12, 13, 14, 15, 16 mm or more.

### Embodiment 8

The method of embodiment 1, wherein the balls used for ball milling have diameters of about 4-8 mm and comprise ZrO₂. In some embodiments, stainless steel or other balls made of materials that do not interact with the Te and Sn being milled may be used.

### Embodiment 9

The method of embodiment 1, wherein a weight ratio of balls used for ball milling to a combined weight of the Sn powder and Te powder is about 2:1-8:1 or any value or subratio thereof. In some embodiments the weight ratio of the balls to a combined weight of the Sn and Te powders will range from about 0.25:1 to 20:1, for example, 0.25:1, 0.5:1, 1:1, 2:1, 3:1, 4:1, 5:1, 6:1, 7:1, 8:1, 9:10, 10:1, 15:1, or 20:1 or any intermediate ratio.

### Embodiment 10

The method of embodiment 1, wherein a weight ratio of balls used for ball milling to a combined weight of the Sn powder and Te powder is about 4:1-6:1 or any value or subratio thereof.

### Embodiment 11

The method of embodiment 1, wherein the ball milling is continued until at least 10, 20, 30, 40, 50, 60, 70, 80, 90, 95, 96, 97, 98, 99, or 100 wt %, or any intermediate value within this range, of all Sn and Te is in a form of a homogenous mixture of SnTe particles in solid solution. In some embodiments ball milling may be terminated before all of the SnTe is in the form of a solid solution, for example, ball milling may be discontinued when 10, 20, 30, 40, 50, 60, 70, 80, 90, 95, 99 wt. % or <100 wt. % of the SnTe is in the form of SnTe particles in solid solution. This range includes all intermediate values and subranges.

### Embodiment 12

The method of embodiment 1, further comprising spark plasma sintering the crystalline SnTe nanoparticles to produce a sintered material comprising SnTe.

### Embodiment 13

The method of embodiment 1, further comprising spark plasma sintering the crystalline SnTe nanoparticles at about 40-60 MPa and about 450-650° C. to produce a SnTe alloy. In some embodiments, spark plasma sintering may be performed at about 20, 30, 40, 50, 60, 70, or 80 MPa or at a temperature ranging from 300, 400, 500, 600, 700 or 800° C.

### Embodiment 14

SnTe nanoparticles in solid solution, fcc crystalline phase, having an average diameter of about 50 nm, for example, having an average diameter of 50 nm±1, 2, 3, 4, 5, 6, 7, 8, 9 or 10 nm.

### Embodiment 15

The SnTe nanoparticles of embodiment 14, wherein at least 90 wt % of the Sn and Te is in a form of a homogenous mixture of SnTe particles in the solid solution. In some embodiments a composition may contain both SnTe nanoparticles in solid solution as well as Sn and/or Te in another form, such as in an amorphous or unblended form. A content of SnTe nanoparticles in solid solution in such a composition may range from 5, 10, 20, 30, 40, 50, 60, 70, 80, 90, 95, 96, 97, 98, 99 wt % or <100 wt % of the total amount of Sn and Te is in the form of SnTe particles in solid solution.

### Embodiment 16

The SnTe nanoparticles of embodiment 14 that further comprises lead or one or more other ingredients or dopants.

### Embodiment 17

The SnTe nanoparticles of embodiment 14 that are substantially lead free, for example, that contain less than 0.001, 0.005, 0.01, 0.05, 0.1, 0.5, 1, 1.5, or 2 wt % lead. In some embodiments the SnTe nanoparticles will be a binary mixture of Sn and Te without substantial amounts of lead or other ingredients such as dopants, for example less than 0.001, 0.005, 0.01, 0.05, 0.1, 0.5, 1, or 2 wt % of other elements besides Sn and Te.

### Embodiment 18

The SnTe nanoparticles of embodiment 14, wherein less than 25, 20, 15, 10, 5, 4, 3, 2, 1, 0.5, 0.1, 0.05, or 0.01 wt % of the SnTe is in an amorphous state.

### Embodiment 19

A SnTe material produced by spark plasma sintering the SnTe nanoparticles of embodiment 14.

### Embodiment 20

The SnTe material of embodiment 19 that is produced by spark plasma sintering the SnTe nanoparticles at about 40-60 MPa and about 450-650° C.

### Embodiment 21

A p-type semiconductor or other electronic component comprising the SnTe material of embodiment 19.

### Embodiment 22

A thermoelectric device or component thereof comprising the SnTe material of embodiment 19.

SnTe:

a mixture or alloy of tellurium and tin. SnTe may be in a crystalline form, in the form of a solid solution, or in an amorphous form. SnTe exists in 3 crystal phases. At low temperatures tin telluride exists in rhombohedral phase also known as α-SnTe. At room temperature and atmospheric pressure, Tin Telluride exists in NaCl-like cubic crystal phase, known as β-SnTe. While at 18 kbar pressure, β-SnTe transforms to γ-SnTe, orthorhombic phase, space group Pnma. This phase change is characterized by 11 percent increase in density and 360 percent increase in resistance for γ-SnTe; see Kafalas, J. A.; Mariano, A. N., High-Pressure Phase Transition in Tin Telluride. Science 1964, 143 (3609), 952-952; incorporated by reference).

A Solid Solution:

A solid in which components are compatible and form a unique phase. A solid-state solution contains one or more solutes in a solvent. Such a multi-component system is considered a solution rather than a compound when the crystal structure of the solvent remains unchanged by addition of the solutes, and when the chemical components remain in a single homogeneous phase.

Homogenous.

A homogenous mixture of particles according to the invention will have substantially the same diameters. For example, in homogenous mixture of SnTe particles having an average diameter of 50 nm at least 70, 80, 90, 95 or 99% of the particles will have diameters within the range 30-70 nm, 40-60 nm, 45-55 nm, or 49.5 to 50.5 nm.

Amorphorization:

the act or process of making something structurally amorphous or of becoming structurally amorphous.

A ball mill is a type of grinder used to grind and blend materials for use in mineral dressing processes, paints, pyrotechnics, ceramics and selective laser sintering. A ball mill works on the principle of impact and attrition: size reduction is done by impact as the balls drop from near the top of the shell. Further description of ball mills is incorporated by reference to the text available at en.wikipedia.org/wiki/Ball_mill (last accessed Oct. 30, 2017).

Mixing/Homogenization.

In most embodiments the starting materials for production of a consolidated SnTe material or alloy are in the forms of particles produced by the ball milling procedures described herein. These particles may be provided directly from ball milling or ball milled particles may be admixed or doped with additional materials to become part of a sintered produced or to otherwise facilitate sintering. In some embodiments, the starting materials will be further homogenized, for example, by use of an ultrasonic sonicator probe, optionally followed by drying and further mixing using a mortar and pestle to provide a substantially uniform distribution of SnTe particles and, optionally, other ingredients for doped or non-binary mixtures.

Thermoelectric materials show the thermoelectric effect in a strong or convenient form. The thermoelectric effect refers to phenomena by which either a temperature difference creates an electric potential or an electric potential creates a temperature difference. These phenomena are known more specifically as the Seebeck effect (converting temperature to current), Peltier effect (converting current to temperature), and Thomson effect (conductor heating/cooling). While all materials have a nonzero thermoelectric effect, in most materials it is too small to be useful. However, low-cost materials that have a sufficiently strong thermoelectric effect (and other required properties) could be used in applications including power generation and refrigeration. Thermoelectric materials are used in thermoelectric systems for cooling or heating in niche applications, and are a way to regenerate electricity from waste heat.

ZT or figure of merit. The performance of thermoelectric materials depends on their dimensionless thermoelectric figure-of-merit ZT=(S2σ/κ)T, where S is the Seebeck coefficient, σ the electrical conductivity, κ the thermal conductivity, and T the absolute temperature at which the properties are measured. The numerator S2σ is called the power factor; see Rowe, D. M. CRC Handbook of Thermoelectrics; CRC Press: Boca Raton, Fla., 1995.

Spark Plasma Sintering (“SPS”) is a process whereby a material in the form of a powder is subjected to heat by applying high direct current in combination with uniaxial pressure. It can result in particles bonding together to form a coherent body with reduced porosity, increased density and improved hardness, toughness and strength.

Spark plasma sintering is performed at a pressure range suitable for consolidating particles of SnTe alloy. For example, at a pressure ranging from 10-100 MPA, preferably from 25 to 75 MPa, and most preferably from 40-60 MPa. These ranges include all intermediate values and subranges such as 10, 20, 25, 30, 35, 40, 45, 50, 55, 60, 65, 70, 75, 80, 85, 90, 95, <100 and 100 MPa.

Spark plasma sintering may be performed at a temperature sufficient to consolidate SnTe alloy particles, preferably at a temperature ranging from 300° C. to 800° C., and most preferably at a temperature ranging from 500-600° C. These ranges include all intermediate values and subranges such as 300, 350, 400, 450, 500, 550, 600, 650, 700, 750, 800, and >800. In some embodiments of the method, the heating rate will range from 5, 10, 20, 25, 30, 35, 40, 45, 50, 55, 60, 65, 70, 75, 80, 85, 90, 95, 100, 125, 150, 200 or >200° C./min; preferably a heating rate of 25-75° C./min, most preferably about 50° C./min. These ranges include all intermediate values and subranges.

A spark plasma sintering time is selected based on the nature of the staring materials, the time constraints, as well as on the final properties desired in the sintered composite produced. Many embodiments of the invention have sintering or holding times of less than about 1-60 mins. This range includes all intermediate values and subranges such as about 1, 5, 10, 15, 20, 25, 30, 35, 40, 45, 50 and 60 mins.

Nano-sized refers to an average particle size ranging from 1 nm to <1,000 nm, which range includes all intermediate values and subranges, such as 1, 2, 5, 10, 15, 20, 25, 30, 35, 40, 45, 50, 60, 70, 75, 100, 150, 200, 250, 300, 350, 400, 450, 500, 550, 600, 650, 700, 750, 800, 850, 900, 950, and <1,000 nm (transmission electron microscopy, TEM). SnTe particles used for SPS sintering preferably, range in size from 10 nm to 200 nm, more preferably, 50 nm or less (TEM).

Alternative mixtures. As shown herein, careful selection of ball milling conditions produces a SnTe alloy is the form of a solid solution without substantial amorphorization and may be industrially applied to produce large quantities (e.g., hundreds of kilograms) of SnTe nanoparticles. This same procedure may be practiced with other mixtures of starting materials besides or in addition to Te and Sn. For example, bulk processing of other binary, ternary, or other combinations of ingredients such as Te—Bi, Te—Sb, Te—In and Sn—Bi, Sn—Sb, Sn—In and Sb—Bi, and Sb—In, as well as mixtures, including Te—Se and those described above, doped with Bi, Sb, In, Cu and Zn or other metals for production of semiconductors, thermoelectric elements, such as those in thermoelectric generators, thermoelectric coolers, such as portable commercial coolers or coolers for electronic components, heat pumps, infrared detectors, solar panels, superconductors, phase change memory chips, may also be produced using the procedures disclosed herein.

### Example

Experimental Procedure.

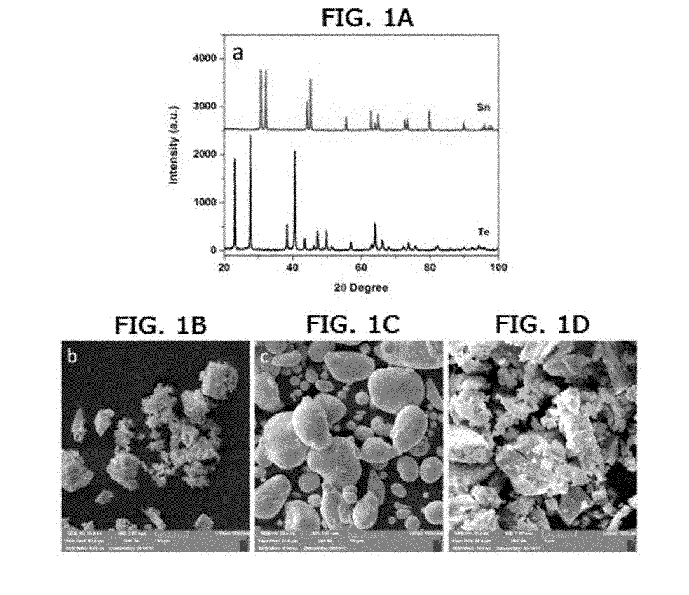

Chemicals were procured from Alfa Aesar in the form of elemental powders with following purity and particle sizes; Tin (Sn: 99.5%, —100 mesh) and Tellurium (Te: 99.5%—200 mesh). Starting powders were characterized by XRD and FESEM before ball milling and FIG. 1A represents XRD pattern of Sn and Te powders and FIGS. 1B and 1C show the corresponding morphologies of respective Sn and Te powders. FIG. 1D is magnified morphology of the Te powder and it is observed large particles as well as very fine particles on the FESEM micrograph.

The stoichiometric of SnTe was carefully weighed (Sn: 48.20 g and Te: 51.80 g) and balanced powder mixture was transferred into a Zirconia bowl (volume of 700 cc) with 5 mm diameter Zirconia (ZrO₂) balls.

The weight of the balls to the powders was measured at a 5:1 ratio.

The Bowl was fastened into a ball mill (Union process, HD-01/HDDM-01-Lab Attritor) and powder mixture was milled at the speed of 300 RPM. Powder mixture was dry milled for 5 h over the flow of argon to avoid any moisture (from air) contamination.

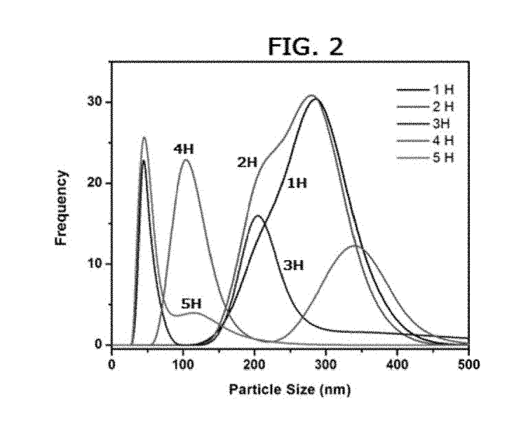

Milling was conducted for maximum five (5) h and small amount of sample was collected at every 1 hour interval from the ball milling bowl for the various analyses. The effect of milling time on the size distribution and reduction is indicated in FIG. 2. Graph shows that as the milling time increase from 1 to 5 h the frequency of the distribution increases and the curve shifted towards smaller particle sizes. Ball milled powders were analyzed FESEM to observe the size reduction and distribution. While not being bound to any particular technical explanation, the Sn powder appears to have been dissolved into Te brittle particles during milling because it was difficult to assess the initial morphology of the Sn powder in the mixture.

Small amounts of powder samples were collected at 30 min, then hourly at 1, 2, 3, 4, and 5 hours.

The effect of milling time on the size distribution and reduction is indicated in FIG. 2. The graph shows that as the milling time increases from 1 to 5 hours the frequency of the distribution increases and the curve shifts leftward towards smaller sizes.

Compositional Analysis.

An elemental compositional analysis was performed by an Energy Dispersive X-ray Spectrometer (EDS) (X-Max^{N}, silicon drift detector, Oxford Instruments) equipped with INCA Energy Systems.

Surface area. BET (N₂-physisorption-Micromeritics, ASAP 2020) was used to study the surface area of the milled powders in liquid nitrogen at −196° C. Prior to adsorption analysis, samples were degassed up to 100° C. for 1 hour to remove adsorbed gas and water.

Particle Size.

Particle size distribution of the ball milled powders was analyzed using a Microtrac Particle size analyzer (Model S3500/Zetatrac) based on the principle of dynamic light scattering (DLS). Particles were dispersed in the liquid medium of ethanol to reduce particle agglomeration in probe sonicator (Sonics, Vibra cell-VCX 750) before DLS.

Thermal Analysis.

Differential thermal analysis (DTA) was (STA 449F3-Jupiter by Netzsch) employed to determine thermo-physical properties of milled powders. The measurements were made up to 900° C. in flowing argon atmosphere, using alumina crucible and a heating rate of 10°/min. The onset point of an endothermic shift in the DTA curve was taken as representing as corresponding to Tm of the SnTe powder.

X-Ray Diffraction.

All powder samples were characterized by X-ray diffraction (XRD), to detect the phase(s) present in the milled powder samples by Rigaku MiniFlex X-ray diffractometer (Japan) with Cu K_{α1}, radiation (γ=0.15416 nm), XRD tube current of 10 mA, and an accelerating voltage of 30 kV. A field emission scanning electron microscope (FESEM, Lyra3, Tescan, Czech Republic) with an accelerating voltage of 30 kV was used to characterize the morphologies of the powders and sintered samples.

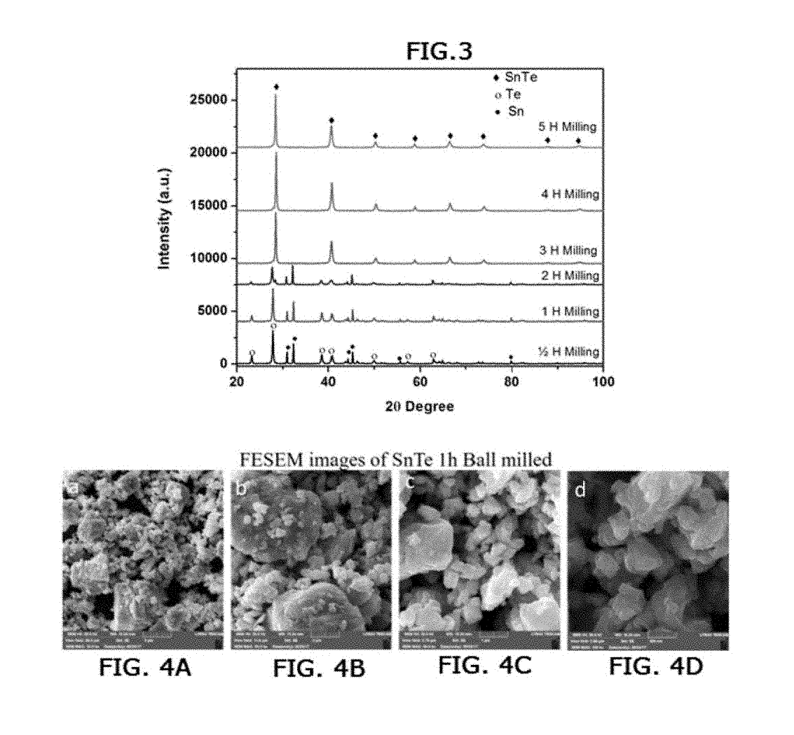

FIG. 3 presents the X-ray diffraction (XRD) patterns of SnTe ball milled powders admixed for various durations. As the ball milling proceeds the peaks of both elements Sn and Te decrease and third phase peaks start to appear in the spectrum. After 3 hours, the ball milling spectrum displays the formation of new phase of SnTe solid solution and peak broadening observed in the further ball milling in the spectrum.

The powder particles sizes were reduced during ball milling and due to this the surface free energy of the particles was increased. The FIG. 3 spectrum was acquired from sample ball milled at 5 hours was a single phase indexed to the face-centered structure (ICDD 03-065-2945 space group Fm3m). No evidence of any other phase(s) was found even after 3 h ball milling.

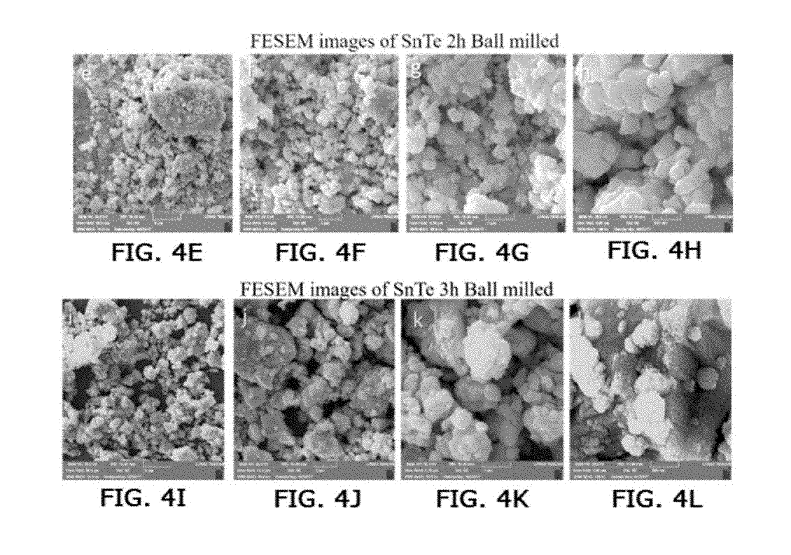

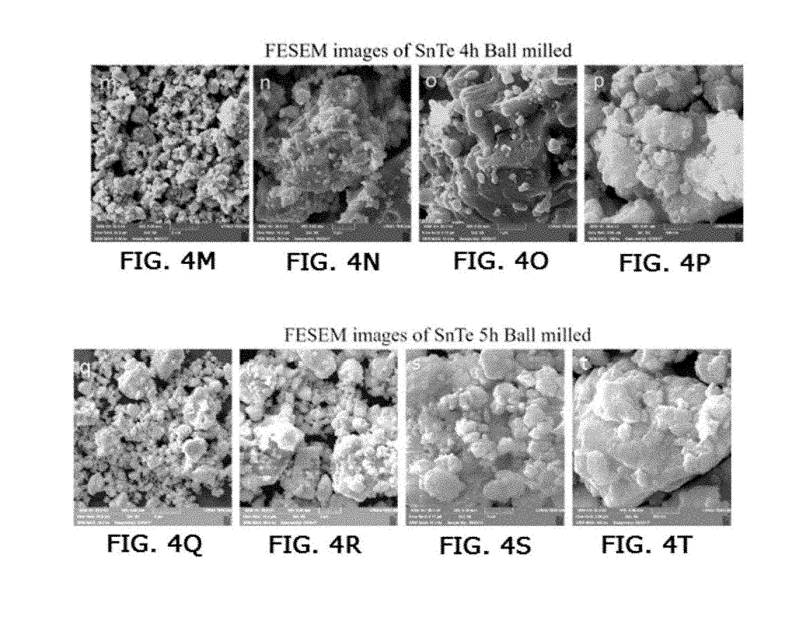

FIGS. 4A-4T—show the field emission scanning electron microscope (FESEM) images; and the low- and high-magnification images of the nanopowders after ball milling for 1, 2, 3, 4, or 5 hours.

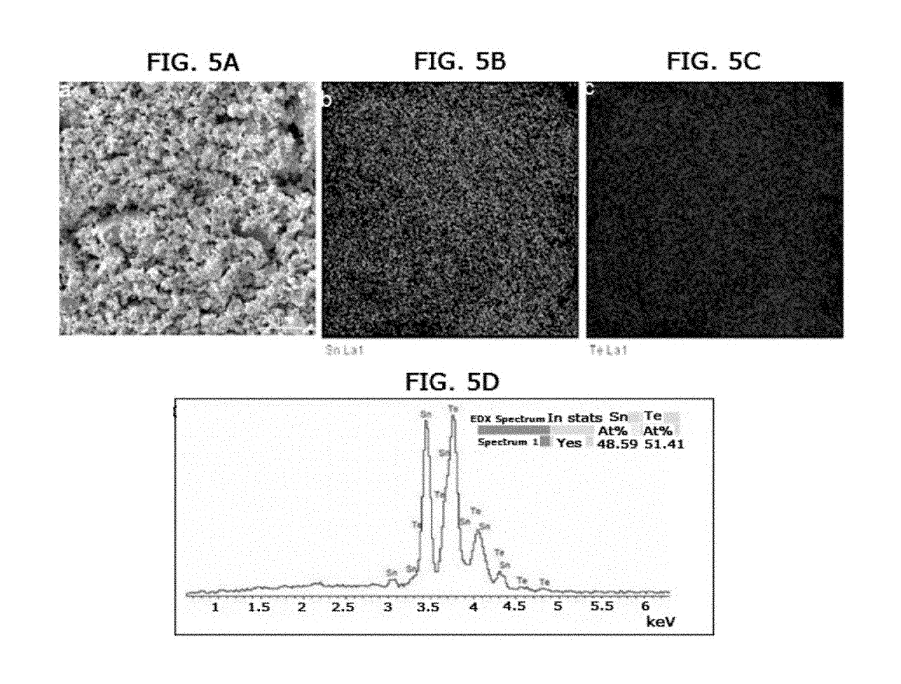

The XRD patterns verify that the powder is in a predominantly single phase and the broadened diffraction peaks indicate that the particles are small, which is also confirmed by the FESEM image at high-magnification. Not much difference was observed in the morphology of the particles at 1 and 2 hours of ball milling but as the ball milling proceeded further the morphology of the particles changed. It is observed in FIGS. 4I-4T that particles size deceased as the ball milling proceeded at 3, 4 and 5 hours. It was observed from FESEM micrographs that Sn particles were wrapped and melted within Te particles and some degree of distribution as shown in FIGS. 4Q-4T. Similar observation noted in FIG. 2 and FIG. 3 where particle size distribution and XRD are recorded respectively. These findings confirm that XRD, DLS and FESEM results agree. FIG. 5 shows the EDX of sample milled for 5 hours and corresponding mapping revealed the distribution and atomic ratio of Sn:48.59 and Te:51.41 which reflected the starting ratio as well as promising distribution of the SnTe powders. EDX mapping and spectrum confirms the XRD findings quite well.

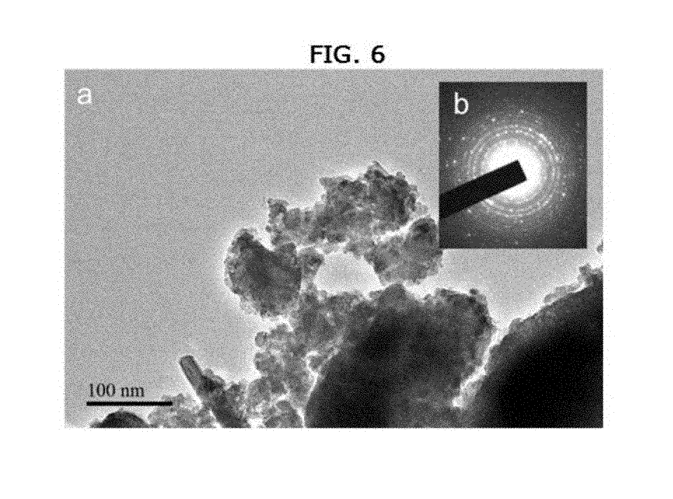

The crystallographic and structural analyses of the sample were carried out by conventional transmission electron microscopy. The TEM image (FIG. 6A) also shows that the nanoparticles have sizes ranging up to 50 nm and confirms the crystallinity of the nanoparticles shown in the XRD of FIG. 3. Surprisingly, ball milling played a significant role in demolishing large crystal size and provided a very small crystal size around 50 nm after 5 hours ball milling. FIG. 6B shows the defused spots which confirmed the presence nanoparticles and tiny crystals of the SnTe alloy prepared via ball milled powder.

X-ray diffraction patterns (FIG. 3) of SnTe powder mixture milled at ½ hour to 5 hours confirmed the formation of SnTe mechanically induced solid solution of nanosize particles. This result has not been previously reported by conventional ball milling procedures. While not being bound to a particular technical explanation, conventional ball milling appears to result in amorphorization of a SnTe powder mixture containing various elements or binary or ternary or more systems due to harsh or extensive ball milling. In contrast, the select conditions of the method of the invention form a desirable solid solution of SnTe alloy while substantially reducing amorphorization

Consolidation.

Consolidation of the powder mixture was performed by spark plasma sintering (SPS) technique (FCT system, model HP D5, Germany) of the milled powder mixtures. The powder mixture was placed in a 12.7 mm graphite die, and then pressed at 50 MPa pressure and heated at a rate of 50° C./min. Samples were sintered at 500 and 600° C. with a holding time of ten minutes. To facilitate removal of the sample from the die and to avoid wear and tear to the punches, a graphite sheet with a thickness of 0.3 mm was inserted between the graphite die and the powders. In addition, to minimize heat loss, the die was covered with a graphite blanket during the sintering process. The sintering temperature was measured using a thermocouple to determine the heat by thermocouple which was placed into the graphite die approximately 2 mm away from the sample.

To remove the graphite sheet and obtain a clean surface, sintered samples were first ground with various grit of SiC papers (coarse to fine grits) and samples were ground and polished using an AutoMet 300 Buehler grinding machine; Al Malki, M. M., et al., Effect of Al metal precursor on the phase formation and mechanical properties of fine-grained SiAlON ceramics prepared by spark plasma sintering. Journal of the European Ceramic Society, 2017. 37(5): p. 1975-1983; Khan, R. M. A., et al., Development of a single-phase Ca-α-SiAlON ceramic from nanosized precursors using spark plasma sintering. Materials Science and Engineering: A, 2016. 673: p. 243-249 incorporated herein by reference.

Density.

Following SPS and grinding, the densities of the sintered samples were measured based on Archimedes' method with deionized water as the immersion medium, and using density determination equipment (METTLER Toledo).

Terminology.

Terminology used herein is for the purpose of describing particular embodiments only and is not intended to be limiting of the invention.

The headings (such as “Background” and “Summary”) and sub-headings used herein are intended only for general organization of topics within the present invention, and are not intended to limit the disclosure of the present invention or any aspect thereof. In particular, subject matter disclosed in the “Background” may include novel technology and may not constitute a recitation of prior art. Subject matter disclosed in the “Summary” is not an exhaustive or complete disclosure of the entire scope of the technology or any embodiments thereof. Classification or discussion of a material within a section of this specification as having a particular utility is made for convenience, and no inference should be drawn that the material must necessarily or solely function in accordance with its classification herein when it is used in any given composition.

As used herein, the singular forms “a”, “an” and “the” are intended to include the plural forms as well, unless the context clearly indicates otherwise.

It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

As used herein, the term “and/or” includes any and all combinations of one or more of the associated listed items and may be abbreviated as “/”.

Links are disabled by deletion of http: or by insertion of a space or underlined space before www. In some instances, the text available via the link on the “last accessed” date may be incorporated by reference.

As used herein in the specification and claims, including as used in the examples and unless otherwise expressly specified, all numbers may be read as if prefaced by the word “substantially”, “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), +/−15% of the stated value (or range of values), +/−20% of the stated value (or range of values), etc. Any numerical range recited herein is intended to include all subranges subsumed therein.

Disclosure of values and ranges of values for specific parameters (such as temperatures, molecular weights, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10 it also describes subranges for Parameter X including 1-9, 1-8, 1-7, 2-9, 2-8, 2-7, 3-9, 3-8, 3-7, 2-8, 3-7, 4-6, or 7-10, 8-10 or 9-10 as mere examples. A range encompasses its endpoints as well as values inside of an endpoint, for example, the range 0-5 includes 0, >0, 1, 2, 3, 4, <5 and 5.

As used herein, the words “preferred” and “preferably” refer to embodiments of the technology that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the technology. As referred to herein, all compositional percentages are by weight of the total composition, unless otherwise specified. As used herein, the word “include,” and its variants, is intended to be non-limiting, such that recitation of items in a list is not to the exclusion of other like items that may also be useful in the materials, compositions, devices, and methods of this technology. Similarly, the terms “can” and “may” and their variants are intended to be non-limiting, such that recitation that an embodiment can or may comprise certain elements or features does not exclude other embodiments of the present invention that do not contain those elements or features.

Although the terms “first” and “second” may be used herein to describe various features/elements (including steps), these features/elements should not be limited by these terms, unless the context indicates otherwise. These terms may be used to distinguish one feature/element from another feature/element. Thus, a first feature/element discussed below could be termed a second feature/element, and similarly, a second feature/element discussed below could be termed a first feature/element without departing from the teachings of the present invention.

The description and specific examples, while indicating embodiments of the technology, are intended for purposes of illustration only and are not intended to limit the scope of the technology. Moreover, recitation of multiple embodiments having stated features is not intended to exclude other embodiments having additional features, or other embodiments incorporating different combinations of the stated features. Specific examples are provided for illustrative purposes of how to make and use the compositions and methods of this technology and, unless explicitly stated otherwise, are not intended to be a representation that given embodiments of this technology have, or have not, been made or tested.

All publications and patent applications mentioned in this specification are herein incorporated by reference in their entirety to the same extent as if each individual publication or patent application was specifically and individually indicated to be incorporated by reference, especially referenced is disclosure appearing in the same sentence, paragraph, page or section of the specification in which the incorporation by reference appears.

The citation of references herein does not constitute an admission that those references are prior art or have any relevance to the patentability of the technology disclosed herein. Any discussion of the content of references cited is intended merely to provide a general summary of assertions made by the authors of the references, and does not constitute an admission as to the accuracy of the content of such references.

1: A method for forming a SnTe alloy comprising:
ball milling Sn powder with Te powder in an atomic ratio ranging from about 1.0:1.1 to 1.1 to 1.0 for a time and under conditions to produce SnTe nanoparticles having a single phase indexed to a face-centered crystalline (fcc) in solid solution; wherein the nanoparticles have an average diameter ranging from 40 nm to 60 nm.

2. The method of claim 1, wherein the alloy consists of the metals Sn and Te.

3. The method of claim 1, wherein the method produces the SnTe nanoparticles having a single phase indexed to a face-centered crystalline (fcc) without substantial amorphorization of more than 1 wt % of the Sn and Te powders.

4. The method of claim 1, wherein the ball milling is conducted in an inert atmosphere.

5. The method of claim 1, wherein the ball milling is performed for about 3.0 to 7 hours at about 200 to 400 RPM.

6. The method of claim 1, wherein the ball milling is performed for about 4.0 to 6.0 hours at about 250 to 350 RPM.

7. The method of claim 1, wherein the Sn powder with Te powder are ball milled with balls having diameters of about 4-8 mm.

8. The method of claim 1, wherein the Sn powder with Te powder are ball milled with balls comprising ZrO₂ having diameters of about 4-8 mm.

9. The method of claim 1, wherein a weight ratio of balls used for ball milling to a combined weight of the Sn powder and Te powder is about 2:1-8:1.

10. The method of claim 1, wherein a weight ratio of balls used for ball milling to a combined weight of the Sn powder and Te powder is about 4:1-6:1.

11. The method of claim 1, wherein the ball milling is continued until 100 wt % of the Sn and Te is in a form of a homogenous mixture of SeTe nanoparticles having a single phase indexed to a face-centered crystalline (fcc) in solid solution.

12: The method of claim 1, further comprising spark plasma sintering the SnTe nanoparticles to produce a sintered material comprising SnTe.

13. The method of claim 1, further comprising spark plasma sintering SnTe nanoparticles at about 40-60 MPa and about 450-650° C. to produce a SnTe material.

14. SnTe nanoparticles in solid solution, fcc crystalline phase, having an average diameter of about 50 nm±10 nm.

15. The SnTe nanoparticles of claim 14, wherein at least 90 wt % of the Sn and Te is in a form of a homogenous mixture of SnTe particles in the solid solution.

16. The SnTe nanoparticles of claim 14 that further comprise lead or one or more other ingredients or dopants.

17. The SnTe nanoparticles of claim 14 that are lead free except for inevitable impurities.

18. A SnTe material produced by spark plasma sintering the SnTe nanoparticles of claim 14.

19. The SnTe material of claim 18 that is produced by spark plasma sintering the SnTe nanoparticles at about 40-60 MPa and about 450-650° C.

20. A p-type semiconductor or other electronic component, or a thermoelectric device or component thereof, comprising the SnTe material of claim 18.
